(19) United States
(12) Patent Application Publication
(10) Pub. No.: US 2009/0116201 A1
(43) Pub. Date: May 7, 2009

(54) CIRCUIT BOARD MODULE AND METHOD FOR REINFORCING STRUCTURE THEREOF

(75) Inventor: Shin-Chung HSIEH, Taoyuan Hsien (TW)

Correspondence Address: Muncy, Geissler, Olds & Lowe, PLLC, P.O. BOX 1364, FAIRFAX, VA, 22038-1364, US

(73) Assignee: DELTA ELECTRONICS, INC.

(21) Appl. No.: 12/140,592

(22) Filed: Jun. 17, 2008

(30) Foreign Application Priority Data
Nov. 2, 2007 (TW) 096141530

(51) Int. Cl. H05K 1/14; H05K 3/32

(52) U.S. Cl. 361/736; 29/840

(57) ABSTRACT

A circuit board module includes a circuit board and a reinforcing substrate. At least one electronic element is disposed on one surface of the circuit board. The reinforcing substrate is connected to a portion of the surface and disposed around the electronic element. A method for reinforcing the structure of the circuit board module is also disclosed.

### CROSS REFERENCE TO RELATED APPLICATIONS

This Non-provisional application claims priority under 35 U.S.C. §119(a) on Patent Application No(s). 096141530 filed in Taiwan, Republic of China on Nov. 2, 2007, the entire contents of which are hereby incorporated by reference.

### BACKGROUND OF THE INVENTION

1. Field of Invention

The invention relates to a circuit board module and a method for reinforcing the structure thereof.

2. Related Art

By the development of the integrated circuit technology, many kinds of electronic elements can be integrated on a circuit board and applied to various kinds of electronic products. Besides, because the development of electronic products trends towards miniaturization, the circuit board needs to be miniaturized to fit the electronic products. However, if the circuit board is too thin, the structure strength will be insufficient. Thus, the electronic elements formed thereon may be easily damaged due to the improper uses or collisions.

As shown in FIG. 1, a conventional circuit board module 1 includes a circuit board 11, a plurality of electronic elements 12 and a package adhesive 13. The electronic element 12 and the package adhesive 13 are disposed on the circuit board 11. The package adhesive 13 is used to reinforce the structural strength of the circuit board 11.

However, using the package adhesive 13 to reinforce the structure of the circuit board module 1 causes many drawbacks. Firstly, to form the package adhesive 13 on the circuit board 11 needs three processes of dispensing, baking and cooling. The processes make the manufacturing procedure take a long time and need additional apparatuses for dispensing and baking, which increases the cost. Furthermore, the dispensing process easily makes the package adhesive 13 non-uniform, thereby affecting the following assembling process and the production yield. Alternatively, the package adhesive 13 can be formed by injection molding so as to encapsulate the circuit board. However, utilizing the injection molding technology needs the molds and injection molding apparatuses, which may increase the cost and the production time. Besides, the circuit boards produced by the injection molding can not be repaired, so that the production yield will be decreased.

### SUMMARY OF THE INVENTION

In view of the foregoing, the invention is to provide a circuit board module and a method for reinforcing the structure thereof that can simplify the manufacturing processes and increase the production yield.

To achieve the above, a circuit board module according to the present invention includes a circuit board and a reinforcing substrate. At least one electronic element is disposed on one surface of the circuit board. The reinforcing substrate is connected to a portion of the surface and disposed around the electronic element.

In addition, the present invention also discloses a method for reinforcing the structure of a circuit board module. The method includes the following steps of: disposing a conductive connection layer on a surface of a circuit board; disposing at least one electronic element and a reinforcing substrate to contact the conductive connection layer; and connecting the electronic element and the reinforcing substrate to the surface of the circuit board.

As mentioned above, the reinforcing substrate of the present invention is connected to the circuit board through the surface mount technology (SMT) so as to reinforce the structure of the circuit board module. Compared with the prior art, the conventional package adhesive is not utilized in the present invention so that the manufacturing processes and the apparatuses of dispensing, baking and cooling are unnecessary. Additionally, the reinforcing substrate and the electronic element can be simultaneously connected to the circuit board to simplify the manufacturing processes and decrease the production time and cost. Furthermore, the usage of the reinforcing substrate can eliminate the non-uniform of the adhesive so that the production yield can be increased. In addition, the reinforcing substrate is provided without utilizing the conventional injection molding, so that the aim of reinforcing the circuit board can be achieved with lower production cost and higher production yield.

### BRIEF DESCRIPTION OF THE DRAWINGS

The present invention will become more fully understood from the detailed description given herein below and accompanying drawings which are given by way of illustration only, and thus are not limitative of the present invention, and wherein:

FIG. 1 is a schematic diagram of a conventional circuit board module;

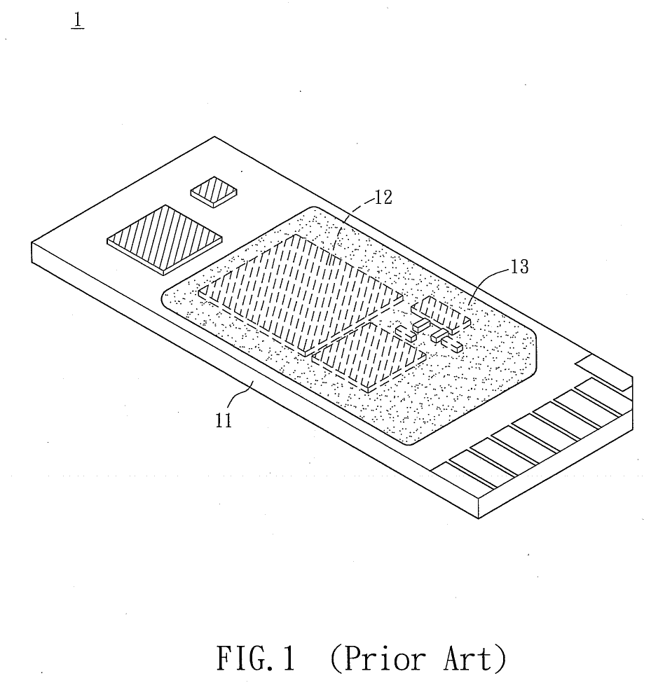

FIG. 2 is a schematic diagram of a circuit board module according to an embodiment of the present invention; and

FIG. 3 is a flow chart of a method for reinforcing the structure of a circuit board module according to the embodiment of the present invention.

### DETAILED DESCRIPTION OF THE INVENTION

The present invention will be apparent from the following detailed description, which proceeds with reference to the accompanying drawings, wherein the same references relate to the same elements.

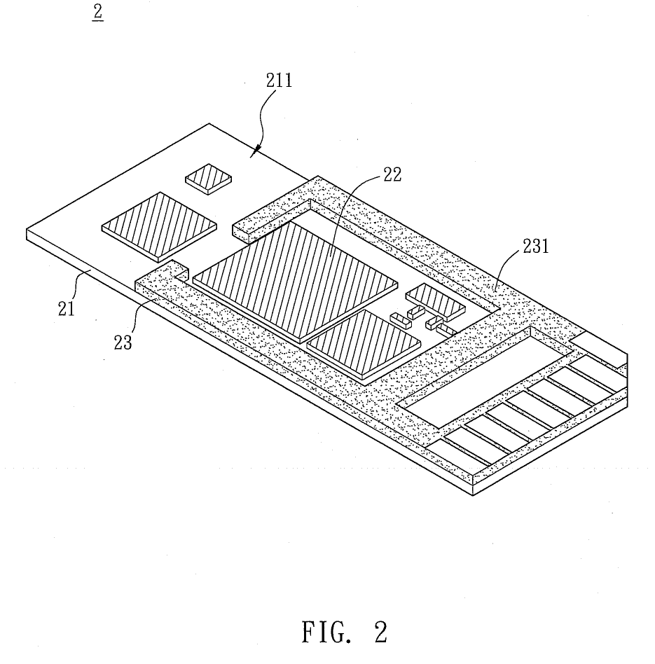

As shown in FIG. 2, a circuit board module 2 according to an embodiment of the present invention includes a circuit board 21, at least one electronic element 22 and a reinforcing substrate 23. To be noted, the circuit board module 2 of the present invention can by any kind of circuit board module, and is preferably the circuit board module that can be plugged into the socket of an electronic apparatus. The circuit board module 2 can be a memory card, a WLAN card or a GPS card, for example. Moreover, the memory card can be a Compact Flash (CF) card, a Security Digital (SD) card, a MultiMedia Card (MMC) or a Memory stick (MS).

The electronic element 22 is disposed on a surface 211 of the circuit board 21. In the embodiment, the electronic element 22 can be a passive component or an active component. The reinforcing substrate 23 is connected to a portion of the surface 211 and disposed on the circuit board 21 through the SMT. The reinforcing substrate 23 is not limited in materials and shapes in the present invention. The material of the reinforcing substrate 23 is, for example but not limited to, resin, ceramics, metal or alloy.

In the embodiment, the reinforcing substrate 23 is disposed along at least one portion of the circumference of the circuit board 21 and disposed around at least one portion of the electronic element 22 for protecting the electronic element 22. To be noted, the height of the electronic element 22 must be not larger than that of the reinforcing substrate 23. In addition, the reinforcing substrate 23 has a metal layer 231 which is a grounding metal layer to prevent the electromagnetic interference (EMI). The grounding metal layer 231 is electrically connected to a grounding point of the circuit board 21 through a wire or a via (not shown in the drawing) of the reinforcing substrate 23. The material of the reinforcing substrate 23 can include metal or alloy.

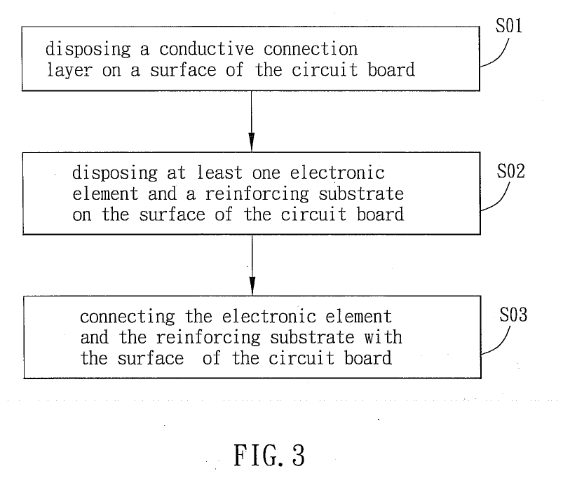

As shown in FIG. 3, a method for reinforcing the structure of a circuit board module according to the embodiment of the present invention includes the following steps S01 to S03. The illustration of the method will be described hereinafter with reference to FIGS. 2 and 3.

First, the step S01 is to dispose a conductive connection layer on a surface 211 of the circuit board 21. The conductive connection layer is, for example, a solder paste.

Then, the step S02 is to dispose at least one electronic element 22 and a reinforcing substrate 23 on the surface 211 of the circuit board 21.

Finally, the step S03 is to connect the electronic element 22 and the reinforcing substrate 23 with the surface 211 of the circuit board 21. In the embodiment, the electronic element 22 and the reinforcing substrate 23 are connected with the surface 211 of the circuit board 21 through the reflow process. Accordingly, the electronic element 22 and the reinforcing substrate 23 can be simultaneously connected on the circuit board 21 through the SMT. Because the main features of the reinforcing substrate 23 and the configurations of the reinforcing substrate 23 and the circuit board 21 are illustrated in the previous embodiment, the detailed descriptions thereof are omitted.

In summary, a reinforcing substrate of the invention is connected to a circuit board through the surface mount technology (SMT) so as to reinforce the structure of a circuit board module. Compared with the prior art, the conventional package adhesive is not utilized in the invention so that the manufacturing processes and the apparatuses of dispensing, baking and cooling are unnecessary. Additionally, the reinforcing substrate and the electronic element can be simultaneously connected to the circuit board to simplify the manufacturing processes and decrease the production time and cost. Furthermore, the usage of the reinforcing substrate can eliminate the non-uniform of the adhesive so that the production yield can be increased. Furthermore, the reinforcing substrate has a grounding metal layer to prevent EMI. In addition, the reinforcing substrate is provided without utilizing the conventional injection molding, so that to the aim of reinforcing the circuit board can be achieved with lower production cost and easier reparation.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A circuit board module comprising:
a circuit board;
at least one electronic element disposed on a surface of the circuit board; and
a reinforcing substrate connected to a portion of the circuit board and disposed around the electronic element.

2. The circuit board module as recited in claim 1, wherein the reinforcing substrate is connected to the circuit board through a surface mount technology.

3. The circuit board module as recited in claim 1, wherein the reinforcing substrate is disposed along at least a portion of the circumference of the circuit board.

4. The circuit board module as recited in claim 1, wherein a height of the electronic element is not larger than that of the reinforcing substrate.

5. The circuit board module as recited in claim 1, wherein a material of the reinforcing substrate comprises resin, ceramics, metal or alloy.

6. The circuit board module as recited in claim 1, wherein the reinforcing substrate comprises a metal layer.

7. The circuit board module as recited in claim 6, wherein the metal layer is grounded.

8. The circuit board module as recited in claim 7, wherein the reinforcing substrate has a via connected to the metal layer and a grounding point of the circuit board.

9. The circuit board module as recited in claim 1, being a memory card, a WLAN card or a GPS card.

10. The circuit board module as recited in claim 9, wherein the memory card comprises a Compact Flash (CF) card, a Security Digital (SD) card, a MultiMedia Card (MMC) or a Memory stick (MS).

11. A method for reinforcing a structure of a circuit board module, comprising steps of:
providing a circuit board;
disposing at least one electronic element on a surface of the circuit board;
providing a reinforcing substrate; and
connecting the electronic element and the reinforcing substrate to the circuit board, wherein the reinforcing substrate is connected to a portion of the circuit board and disposed around the electronic element.

12. The method as recited in claim 11, further comprising a step of forming a conductive connection layer between the reinforcing substrate and the circuit board, and between the electronic element and the circuit board.

13. The method as recited in claim 12, wherein the conductive connection layer is a solder paste.

14. The method as recited in claim 11, wherein the electronic element and the reinforcing substrate are connected to the circuit board through a reflow process.

15. The method as recited in claim 11, wherein the reinforcing substrate is connected to the circuit board through a surface mount technology.

16. The method as recited in claim 11, wherein the reinforcing substrate is disposed along at least a portion of the circumference of the circuit board.

17. The method as recited in claim 11, further comprising a step of forming a metal layer on the reinforcing substrate.

18. The method as recited in claim 17, further comprising a step of grounding the metal layer.

19. The method as recited in claim 18, wherein the metal layer is grounded by electrically connecting to a grounding point of the circuit board through a via.

20. The method as recited in claim 11, wherein a material of the reinforcing substrate comprises resin, ceramics, metal or alloy.
